(19) United States
(12) Patent Application Publication
(10) Pub. No.: US 2022/0181118 A1
(43) Pub. Date: Jun. 9, 2022

(54) APPARATUS FOR GENERATING PLASMA, APPARATUS FOR TREATING SUBSTRATE INCLUDING THE SAME, AND METHOD FOR CONTROLLING THE SAME

(71) Applicant: SEMES CO., LTD., Chungcheongnam-do (KR)

(72) Inventors: Ogsen GALSTYAN, Chungcheongnam-do (KR); Shant ARAKELYAN, Chungcheongnam-do (KR); Young-Bin KIM, Gyeonggi-do (KR); Youn Gun BONG, Gyeonggi-do (KR); Jong-Hwan AN, Gyeonggi-do (KR)

(21) Appl. No.: 17/540,742

(22) Filed: Dec. 2, 2021

(30) Foreign Application Priority Data
Dec. 3, 2020 (KR) 10-2020-0167470

(51) Int. Cl. H01J 37/32

(52) U.S. Cl. CPC H01J 37/3211; H01J 37/3244; H01J 2237/334; H01J 37/32715; H01J 37/32183

(57) ABSTRACT

Disclosed is an apparatus for treating a substrate. The apparatus may include a chamber having a space for treating the substrate therein; a support unit supporting the substrate in the chamber; a gas supply unit supplying gas into the chamber; and a plasma generation unit exciting the gas in the chamber into a plasma state, wherein the plasma generation unit may include high frequency power supply; a first antenna; a second antenna; and a matcher connected between the high frequency power supply and the first and second antennas, wherein the matcher may include a current distributor distributing a current to the first antenna and the second antenna, and the current distributor includes a first capacitor disposed between the first antenna and the second antenna; a second capacitor connected with the second antenna in series; and a third capacitor connected with the second antenna in parallel, wherein the first capacitor and the second capacitor may be provided as variable capacitors.

### CROSS-REFERENCE TO RELATED APPLICATIONS

This application claims priority to and the benefit of the Korean Patent Application No. 10-2020-0167470 filed in the Korean Intellectual Property Office on Dec. 3, 2020, the entire contents of which are incorporated herein by reference.

### TECHNICAL FIELD

The present invention relates to an apparatus for generating plasma, an apparatus for treating a substrate including the same, and a method for controlling the same, and more particularly, to an apparatus for generating plasma using a plurality of antennas, an apparatus for treating a substrate including the same, and a method for controlling the same.

### BACKGROUND ART

A semiconductor manufacturing process may include a process of treating a substrate using plasma. For example, in an etching process of the semiconductor manufacturing process, a thin film on the substrate may be removed using the plasma.

To use the plasma in the substrate treating process, a plasma generation unit capable of generating the plasma is mounted in a process chamber. The plasma generation unit is greatly divided into a capacitively coupled plasma type and an inductively coupled plasma type according to a plasma generation method. Among them, in a CCP type source, two electrodes are disposed in the chamber to face each other and an RF signal is applied to any one or both of the two electrodes to form an electric field in the chamber and generate the plasma. On the contrary, in an ICP type source, one or more coils are provided in the chamber and an RF signal is applied to the coils to induce an electromagnetic field in the chamber and generate the plasma.

When two or more coils are provided in the chamber and the two or more coils receive power from an RF power supply, a current distributor is provided between the RF power supply and the coils, and the etching process may be performed in all regions of the substrate by controlling the current distributor. However, when the etching process is performed using a conventional current distributor, there is a problem that an etching rate varies in a center region and an edge region of the substrate due to the density imbalance of the plasma in the chamber.

### SUMMARY OF THE INVENTION

The present invention has been made in an effort to provide an apparatus for generating plasma capable of performing an etching process so that an etching rate is uniform in all regions of the substrate, an apparatus for treating a substrate including the same, and a method for controlling the same.

The problem to be solved by the present invention is not limited to the above-mentioned problems. The problems not mentioned will be clearly understood by those skilled in the art from the present specification and the accompanying drawings.

An exemplary embodiment of the present invention provides an apparatus for treating a substrate.

The apparatus may include a chamber having a space for treating the substrate therein; a support unit supporting the substrate in the chamber; a gas supply unit supplying gas into the chamber; and a plasma generation unit exciting the gas in the chamber into a plasma state, wherein the plasma generation unit may include high frequency power supply; a first antenna; a second antenna; and a matcher connected between the high frequency power supply and the first and second antennas, wherein the matcher may include a current distributor distributing a current to the first antenna and the second antenna, and the current distributor includes a first capacitor disposed between the first antenna and the second antenna; a second capacitor connected with the second antenna in series; and a third capacitor connected with the second antenna in parallel, wherein the first capacitor and the second capacitor may be provided as variable capacitors.

In the exemplary embodiment, the third capacitor may be provided as a fixed capacitor, and the current distributor may be disposed between the high frequency power supply, the first antenna and the second antenna.

In the exemplary embodiment, the current distributor may distribute the current to the first antenna and the second antenna by adjusting the capacitances of the first capacitor and the second capacitor.

In the exemplary embodiment, the current distributor may control a current ratio of the currents flowing in the first antenna and the second antenna by adjusting the capacitance of the second capacitor.

In the exemplary embodiment, the current distributor may perform a phase control between the currents flowing in the first antenna and the second antenna by adjusting the capacitance of the second capacitor.

In the exemplary embodiment, the current distributor may set a resonance range by adjusting the capacitance of the first capacitor within a predetermined range.

In the exemplary embodiment, the capacitance range of the first capacitor may be 20 to 25 pF or 180 to 185 pF.

Another exemplary embodiment of the present invention provides a control method for a plasma generating apparatus.

The method may include distributing a current to the first antenna and the second antenna by adjusting the capacitances of the first capacitor and the second capacitor.

In the exemplary embodiment, a current ratio control and a phase control of the currents applied to the first antenna and the second antenna may be performed by adjusting the capacitance of the second capacitor.

In the exemplary embodiment, the phase control may be performed by adjusting a value of the capacitance of the second capacitor in a phase control range of the second capacitor.

In the exemplary embodiment, the phase control range of the second capacitor may be a region having a higher capacitance of the second capacitor based on a resonance of the second antenna.

In the exemplary embodiment, the second capacitor may control an etching rate outside the substrate.

According to the present invention, it is possible to provide a uniform etching rate in all regions of the substrate by adjusting a resonance point of the coil in the etching process to adjust a current ratio in a specific range.

Further, it is possible to provide a uniform etching rate in all regions of the substrate by adjusting a capacitance in the etching process to control a phase between the first antenna and the second antenna.

The effect of the present invention is not limited to the foregoing effects. Non-mentioned effects will be clearly understood by those skilled in the art from the present specification and the accompanying drawings.

### BRIEF DESCRIPTION OF THE DRAWINGS

FIG. 1 is a diagram illustrating a substrate treating apparatus according to an exemplary embodiment of the present invention.

FIG. 2 is a diagram illustrating a plasma generation unit according to an exemplary embodiment of the present invention.

FIG. 3 is a diagram for describing an etching rate in a substrate treating apparatus according to a conventional exemplary embodiment.

FIG. 4 is a diagram for describing adjusting a CR according to an exemplary embodiment of the present invention.

FIG. 5 is a diagram for describing performing a control in a first region according to an exemplary embodiment of the present invention.

FIG. 6 is a diagram for describing performing a control in a second region according to an exemplary embodiment of the present invention.

FIG. 7 is a diagram for describing performing a CR and a phase control by adjusting a capacitance of a second capacitor according to an exemplary embodiment of the present invention.

FIGS. 8 and 9 are diagrams illustrating a simulating result according to an exemplary embodiment of the present invention.

FIG. 10 is a diagram illustrating a control method of a plasma generating apparatus according to an exemplary embodiment of the present invention.

### DETAILED DESCRIPTION

Hereinafter, an exemplary embodiment of the present invention will be described more fully hereinafter with reference to the accompanying drawings, in which exemplary embodiments of the invention are shown. However, the present invention can be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the term of “including” any component will be understood to imply the inclusion of stated elements but not the exclusion of any other elements. It will be appreciated that terms “including” and “having” are intended to designate the existence of characteristics, numbers, steps, operations, constituent elements, and components described in the specification or a combination thereof, and do not exclude a possibility of the existence or addition of one or more other characteristics, numbers, steps, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

In an exemplary embodiment of the present invention, a substrate treating apparatus of etching the substrate using plasma will be described. However, the present invention is not limited thereto, and is applicable to various kinds of apparatuses of heating the substrate disposed on the top thereof.

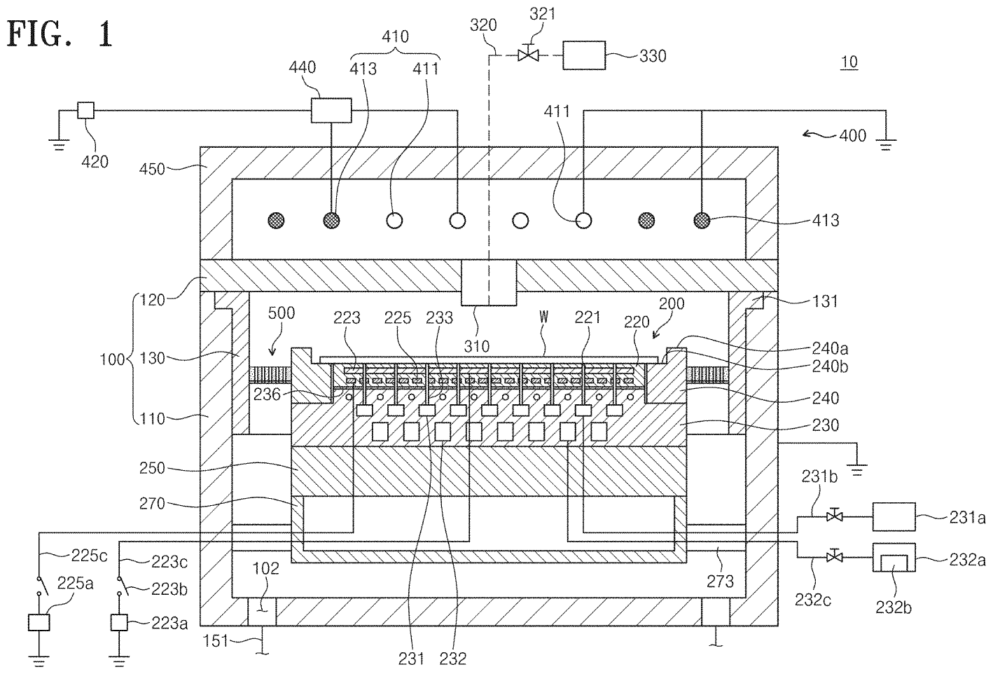

FIG. 1 is a diagram illustrating an example of a substrate treating apparatus 10 according to an exemplary embodiment of the present invention.

Referring to FIG. 1, the substrate treating apparatus 10 treats a substrate W using plasma. For example, the substrate treating apparatus 10 may perform an etching process for the substrate W. The substrate treating apparatus 10 may include a process chamber 100, a support unit 200, a gas supply unit 300, a plasma generation unit 400, and a baffle unit 500.

The process chamber 100 provides a space in which a substrate treating process is performed. The process chamber 100 includes a housing 110, a sealing cover 120, and a liner 130.

The housing 110 has a space with an opened upper surface therein. The inner space of the housing 110 is provided as a treating space in which the substrate treating process is performed. The housing 110 is provided with a metallic material. The housing 110 is provided with an aluminum material. The housing 110 may be grounded. An exhaust hole 102 is formed in the bottom surface of the housing 110. The exhaust hole 102 is connected with an exhaust line 151. Reaction by-products generated in the processing process and gas left in the inner space of the housing may be discharged to the outside via the exhaust line 151. The inside of the housing 110 is decompressed to a predetermined pressure by the exhaust process.

The sealing cover 120 covers the opened upper surface of the housing 110. The sealing cover 120 is provided in a plate shape and seals the inner space of the housing 110. The sealing cover 120 may include a dielectric substance window.

The liner 130 is provided inside the housing 110. The liner 130 is formed in a space with opened upper and lower surfaces. The liner 130 may be provided in a cylindrical shape. The liner 130 may have a radius corresponding to the inner surface of the housing 110. The liner 130 is provided along the inner surface of the housing 110. A support ring 131 is formed at the upper end of the liner 130. The support ring 131 is provided as a ring-shaped plate and protrudes to the outside of the liner 130 along the circumference of the liner 130. The support ring 131 is disposed at the upper end of the housing 110 and supports the liner 130. The liner 130 may be provided with the same material as the housing 110. That is, the liner 130 may be provided with an aluminum material. The liner 130 protects the inner surface of the housing 110. An arc discharge may be generated in the chamber 100 in a process in which process gas is excited. The arc discharge damages peripheral devices. The liner 130 protects the inner surface of the housing 110 to prevent the inner surface of the housing 110 from being damaged by arc discharge. In addition, the liner 130 prevents impurities generated in the substrate treating process from being deposited on an inner wall of the housing 110. The liner 130 is cheaper than the housing 110 and easily replaced. Therefore, when the liner 130 is damaged due to the arc discharge, an operator may replace the liner 130 with a new liner 130.

The substrate support unit 200 may be located inside the housing 110. The substrate support unit 200 supports the substrate W. The substrate support unit 200 may include an electrostatic chuck 210 for adsorbing the substrate W using an electrostatic force. Unlike this, the substrate support unit 200 may also support the substrate W in various methods such as mechanical clamping. Hereinafter, the support unit 200 including the electrostatic chuck 210 will be described.

The support unit 200 includes an electrostatic chuck 210, an insulating plate 250, and a lower cover 270. The substrate support unit 200 may be spaced apart upward from the bottom surface of the housing 110 inside the chamber 100. The electrostatic chuck 210 includes a dielectric plate 220, an electrode 223, a heater 225, a support plate 230, and a focus ring 240.

The dielectric plate 220 may be located at the upper end of the electrostatic chuck 210. The dielectric plate 220 may be provided as a disk-shaped dielectric substance. The substrate W is disposed on the upper surface of the dielectric plate 220. The upper surface of the dielectric plate 220 has a radius smaller than the substrate W. Thus, an edge region of the substrate W is located outside the dielectric plate 220. A first supply flow channel 221 is formed in the dielectric plate 220. The first supply flow channel 221 may be provided to a lower surface from the upper surface of the dielectric plate 220. A plurality of first supply flow channels 221 may be spaced apart from each other, and may be provided as a passage to which a heat transfer medium is supplied to the lower surface of the substrate W.

The lower electrode 223 and the heater 225 are embedded in the dielectric plate 220. The lower electrode 223 is located on the heater 225. The lower electrode 223 is electrically connected with a first lower power supply 223a. The first lower power supply 223a includes a DC power supply. A switch 223b is provided between the lower electrode 223 and the first lower power supply 223a. The first electrode 223 may be electrically connected with the first lower power supply 223a by ON/OFF of the switch 223b. When the switch 223b is turned on, a direct current is applied to the lower electrode 223. The electrostatic force is applied between the lower electrode 223 and the substrate W by the current applied to the lower electrode 223, and the substrate W may be adsorbed to the dielectric plate 220 by the electrostatic force.

The heater 225 may be electrically connected with a second lower power supply 225a. The heater 225 may generate heat by resisting the current applied to the second lower power supply 225a. The generated heat may be transmitted to the substrate W through the dielectric plate 220. The substrate W may be maintained at a predetermined temperature by the heat generated in the heater 225. The heater 225 may include a spiral coil.

The support plate 230 is located below the dielectric plate 220. The lower surface of the dielectric plate 220 and the upper surface of the support plate 230 may adhere to each other by an adhesive 236. The support plate 230 may be provided with an aluminum material. The upper surface of the support plate 230 may be stepped so that a center region is higher than an edge region. The center region of the upper surface of the support plate 230 has an area corresponding to the lower surface of the dielectric plate 220 and may adhere to the lower surface of the dielectric plate 220. The support plate 230 may be formed with a first circulation flow channel 231, a second circulation flow channel 232 and a second supply flow channel 233.

The first circulation flow channel 231 may be provided as a passage for circulating a heat transfer medium. The first circulation flow channel 231 may be formed in a spiral shape inside the support plate 230. Alternatively, the first circulation flow channel 231 may be disposed so that ring-shaped flow channels having different radii have the same center. The respective first circulation flow channels 231 may communicate with each other. The first circulation flow channels 231 are formed at the same height.

The second circulation flow channel 232 may be provided as a passage for circulating a cooling fluid. The second circulation flow channel 232 may be formed in a spiral shape inside the support plate 230. Alternatively, the second circulation flow channel 232 may be disposed so that ring-shaped flow channels having different radii have the same center. The respective second circulation flow channels 232 may communicate with each other. The second circulation flow channel 232 may have a cross-sectional area greater than the first circulation flow channel 231. The second circulation flow channels 232 are formed at the same height. The second circulation flow channel 232 may be located below the first circulation flow channel 231.

The second supply flow channel 233 extends upward from the first circulation flow channel 231 and is provided as the upper surface of the support plate 230. The second supply flow channels 243 are provided in the number corresponding to the first supply flow channels 221, and may connect the first circulation flow channel 231 and the first supply flow channel 221 to each other.

The first circulation flow channel 231 may be connected with a heat transfer medium storage unit 231a via a heat transfer medium supply line 231b. A heat transfer medium may be stored in the heat transfer medium storage unit 231a. The heat transfer medium includes inert gas. According to an exemplary embodiment, the heat transfer medium includes helium (He) gas. The helium gas is supplied to the first circulation flow channel 231 through the supply line 231b, and may be supplied to the lower surface of the substrate W sequentially through the second supply flow channel 233 and the first supply flow channel 221. The helium gas may serve as a medium for transmitting the heat transmitted to the substrate W to the electrostatic chuck 210 in the plasma.

The second circulation flow channel 232 IS connected with a cooling fluid storage unit 232a via a cooling fluid supply line 232c. A cooling fluid is stored in the cooling fluid storage unit 232a. A cooler 232b may be provided in the cooling fluid storage unit 232a. The cooler 232b cools the cooling fluid to a predetermined temperature. Unlike this, the cooler 232b may be provided on the cooling fluid supply line 232c. The cooling fluid supplied to the second circulation flow channel 232 through the cooling fluid supply line 232c may circulate along the second circulation flow channel 232 and cool the support plate 230. The support plate 230 may cool the dielectric plate 220 and the substrate W together while cooling to maintain the substrate W to a predetermined temperature.

The focus ring 240 is disposed in the edge region of the electrostatic chuck 210. The focus ring 240 has a ring shape and is disposed along the circumference of the dielectric plate 220. The upper surface of the focus ring 240 may be stepped so that an outer portion 240a is higher than an inner portion 240b. The inner portion 240b of the upper surface of the focus ring 240 may be located at the same height as the upper surface of the dielectric plate 220. The inner portion 240b of the upper surface of the focus ring 240 may support the edge region of the substrate W located outside the dielectric plate 220. The outer portion 240a of the focus ring 240 is provided to surround the edge region of the substrate W. The focus ring 240 allows the plasma to be concentrated in the area facing the substrate W in the chamber 100.

The insulating plate 250 is located below the support plate 230. The insulating plate 250 is provided in a cross-sectional area corresponding to the support plate 230. The insulating plate 250 is located between the support plate 230 and the lower cover 270. The insulating plate 250 is provided with an insulating material, and electrically insulates the support plate 230 and the lower cover 270 from each other.

The lower cover 270 is located at the lower end of the substrate support unit 200. The lower cover 270 is located to be spaced apart upward from the bottom surface of the housing 110. The lower cover 270 has a space having an opened upper surface therein. The upper surface of the lower cover 270 is covered by the insulating plate 250. Accordingly, an outer radius of the cross-section of the lower cover 270 may be provided with the same length as the outer radius of the insulating plate 250. In the inner space of the lower cover 270, a lift pin module (not illustrated) or the like that moves the substrate W to be transferred from an outer transfer member to the electrostatic chuck 210 may be located.

The lower cover 270 has a connection member 273. The connection member 273 may connect an outer surface of the lower cover 270 and an inner wall of the housing 110 to each other. A plurality of connection members 273 may be provided on the outer surface of the lower cover 270 at a plurality of intervals. The connection member 273 supports the substrate support unit 200 in the chamber 100. In addition, the connection member 273 is connected with the inner wall of the housing 110 so that the lower cover 270 is electrically grounded. A first power supply line 223c connected with the first lower power supply 223a, a second power supply line 225c connected with the second lower power supply 225a, the heat transfer medium supply line 231b connected with the heat transfer medium storage unit 231a, the cooling fluid supply line 232c connected with the cooling fluid storage unit 232a, and the like extend to the inside of the lower cover 270 through the inner space of the connection member 273.

The gas supply unit 300 may supply process gas into the chamber 100. The gas supply unit 300 may include a gas supply nozzle 310, a gas supply line 320, and a gas storage unit 330. The gas supply nozzle 310 is provided at the central portion of the sealing cover 120. An injection port is formed on the lower surface of the gas supply nozzle 310. The injection port is located below the sealing cover 120 and supplies the process gas to a treating space in the chamber 100. The gas supply line 320 connects the gas supply nozzle 310 and the gas storage unit 330 to each other. The gas supply line 320 supplies the process gas stored in the gas storage unit 330 to the gas supply nozzle 310. The gas supply line 320 may be provided with a valve 321. The valve 321 opens and closes the gas supply line 320 and adjusts the flow rate of the process gas supplied through the gas supply line 320.

The plasma generation unit 400 may excite the process gas in the chamber 100 into a plasma state. According to an exemplary embodiment of the present invention, the plasma generation unit 400 may be configured as an ICP type.

The plasma generation unit 400 may include a high frequency power supply 420, a first antenna 411, a second antenna 413, and a matcher 440. The high frequency power supply 420 supplies a high frequency signal. For example, the high frequency power supply 420 may be an RF power supply 420. The RF power supply 420 supplies RF power. Hereinafter, a case where the high frequency power supply 420 is provided as the RF power supply 420 will be described. The first antenna 411 and the second antenna 413 are connected with the RF power supply 420 in series. The first antenna 411 and the second antenna 413 may be provided with coils wound multiple times, respectively. The first antenna 411 and the second antenna 413 are connected to the RF power supply 420 to receive the RF power. The current distributor 430 distributes the current supplied from the RF power supply 420 to the first antenna 411 and the second antenna 413.

The first antenna 411 and the second antenna 413 may be disposed at a position facing the substrate W. For example, the first antenna 411 and the second antenna 413 may be provided on the process chamber 100. The first antenna 411 and the second antenna 413 may be provided in ring shapes. At this time, the radius of the first antenna 411 may be smaller than the radius of the second antenna 413. Further, the first antenna 411 is located inside the upper portion of the process chamber 100, and the second antenna 413 may be located outside the upper portion of the process chamber 100.

According to an exemplary embodiment, the first and second antennas 411 and 413 may be disposed on the side of the process chamber 100. According to an exemplary embodiment, any one of the first and second antennas 411 and 413 may be disposed on the process chamber 100, and the other antenna thereof may also be disposed on the side of the process chamber 100. As long as the plurality of antennas generates plasma in the process chamber 100, the position of the coil is not limited.

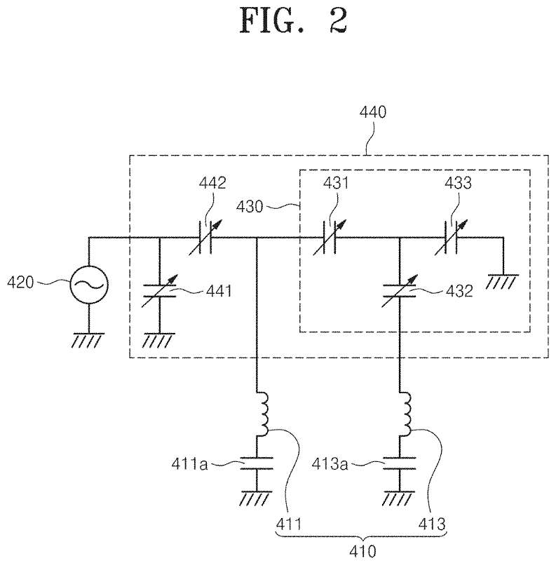

The first antenna 411 and the second antenna 413 receive the RF power from the RF power supply 420 to induce a time-variant electromagnetic field in the chamber, so that the process gas supplied to the process chamber 100 may be excited with the plasma. The matcher 440 may be disposed among the high frequency power supply 420, the first antenna 411 and the second antenna 413. The matcher 440 may include the current distributor 430. The detailed description for the matcher 440 and the current distributor 430 will be described below through FIG. 2.

The baffle unit 500 is located between the inner wall of the housing 110 and the substrate support unit 200. The baffle unit 500 includes a baffle formed with through holes. The baffle is provided in a circular ring shape. The process gas provided in the housing 110 is exhausted to the exhaust hole 102 through the through holes of the baffle. The flow of the process gas may be controlled according to the shape of the baffle and the shapes of the through holes.

FIG. 2 is a diagram illustrating the plasma generation unit 400 according to an exemplary embodiment of the present invention.

As illustrated in FIG. 2, the plasma generation unit 400 may include an RF power supply 420, a first antenna 411, a second antenna 413, and a matcher 440.

The RF power supply 420 may generate an RF signal. According to an exemplary embodiment of the present invention, the RF power supply 420 may generate a sine wave having a predetermined frequency. However, it is not limited thereto, and the RF power supply 420 may generate RF signals having various waveforms, such as a sawtooth wave, a triangle wave, and the like.

The first antenna 411 and the second antenna 413 receive the RF signal from the RF power supply 420 to induce an electromagnetic field and generate the plasma. The plasma generation unit 400 illustrated in FIG. 2 has total two antennas 411 and 413, but the number of antennas is not limited thereto and may be provided in three or more according to an exemplary embodiment.

The matcher 440 may be connected to an output terminal of the RF power supply 420 to match an output impedance of the power supply side with an input impedance of a load side. The matcher 440 may include the current distributor 430. The current distributor 430 may be integrated and implemented in the matcher 440. However, unlike this, the matcher 440 and the current distributor 430 may be provided and implemented as separate components.

The matcher 440 may include variable capacitors 441 and 442 capable of matching the output impedance of the power supply side with the input impedance of the load side. According to an exemplary embodiment, the matcher 440 may include a fourth capacitor 441 connected with the current distributor in parallel and a fifth capacitor 442 connected with the current distributor in series. The fourth capacitor 441 and the fifth capacitor 442 may be provided as variable capacitors. The capacitances of the fourth capacitor 441 and the fifth capacitor 442 are adjusted to perform the impedance matching.

According to an exemplary embodiment, the matcher 440 may include the current distributor 430.

In the present invention, the fourth capacitor 441 and the fifth capacitor 442 are combined to configure a matching circuit and the first capacitor 431, the second capacitor 432, and the third capacitor 433 are combined to configure the current distributor.

The current distributor 430 is provided among the RF power supply 420, the first antenna 411, and the second antenna 413 to distribute the current supplied from the RF power supply 420 to the first antenna 411 and the second antenna 413, respectively. The current distributor 430 according to an exemplary embodiment of the present invention may include a first capacitor 431, a second capacitor 432, and a third capacitor 433. The first capacitor 431 may be disposed between the first antenna 411 and the second antenna 413. The first capacitor 431 may be provided as a variable capacitor. The first capacitor 431 may be adjusted to a predetermined range to adjust a resonance range. The first capacitor 431 may be adjusted to perform tool-to-tool matching (TTTM). The second capacitor 432 may be connected with the second antenna 413 in series. The second capacitor 432 may be provided as a variable capacitor, and may adjust the capacitance of the second capacitor 432 to change the position of a resonance of the second antenna 413. The capacitance of the second capacitor 432 may be adjusted to control a current ratio of the currents flowing in the first antenna 411 and the second antenna 413. In addition, the capacitance of the second capacitor 432 may be adjusted to control a phase of the currents flowing in the first antenna 411 and the second antenna 413. The third capacitor 433 may be connected with the second antenna 413 in parallel. The third capacitor 433 may be provided as a fixed capacitor. According to an exemplary embodiment, an additional phase control region is used through the tuning of the first capacitor 431 and the third capacitor 433 to obtain an additional control knob for plasma treatment tuning.

That is, the first capacitor 431 and the second capacitor 432 may be provided as variable capacitors to adjust the capacitances of the first capacitor 431 and the second capacitor 432, and the capacitances of the first capacitor 431 and the second capacitor 432 may be adjusted to control the plasma density in the chamber 100.

According to an exemplary embodiment, after the capacitance of the first capacitor 431 is adjusted to adjust the resonance range of the second antenna 413, the capacitance of the second capacitor 432 is adjusted to control the current ratio and the phase of the currents flowing in the first antenna 411 and the second antenna 413.

According to an exemplary embodiment of FIG. 2, the first antenna 411 and the second antenna 413 may further include terminal capacitors 411a and 413a connected to respective ends. The terminal capacitors 411a and 413a may be provided as fixed capacitors. The terminal capacitors 411a and 413a may be provided in proportion to the number of coils included in the first antenna 411 and the second antenna 413. According to an exemplary embodiment, one ends of the first antenna 411 and the second antenna 413 are connected to the current distributor 430 and the matcher 440, and the other ends of the first antenna 411 and the second antenna 413 may be connected with the terminal capacitors 411a and 413a, respectively.

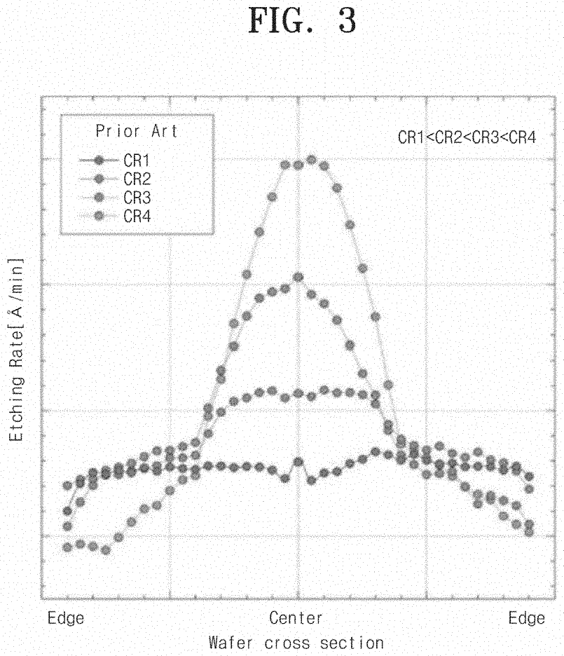

FIG. 3 is a diagram for describing an etching rate in an apparatus for treating a substrate according to a conventional exemplary embodiment.

In a substrate treating apparatus according to a conventional exemplary embodiment, the current distributor has been provided in a configuration including one fixed capacitor and one variable capacitor. In the related art, coupling between the inner coil and the outer coil has been controlled using the fixed capacitor and a current ratio (CR) of the inner coil and the outer coil has been controlled using the variable capacitor. However, in the case of the related art, the etching rate can not be controlled in the edge of a wafer.

FIG. 3 illustrates a radial etching rate profile of a wafer for different CRs. Referring to FIG. 3, in the conventional invention, when the current ratio is controlled through various values, the etching rate is shown. According to FIG. 3, it is illustrated that when the current ratio is variously adjusted, the etching rate in a center region may be variously adjusted. At this time, it can be seen that as the CR value is increased, the etching rate in the center region is increased. However, it can be seen that even if the CR value is increased, the etching rate in an edge region cannot be almost adjusted. That is, a substrate treating apparatus capable of controlling the etching rate in the edge region is required.

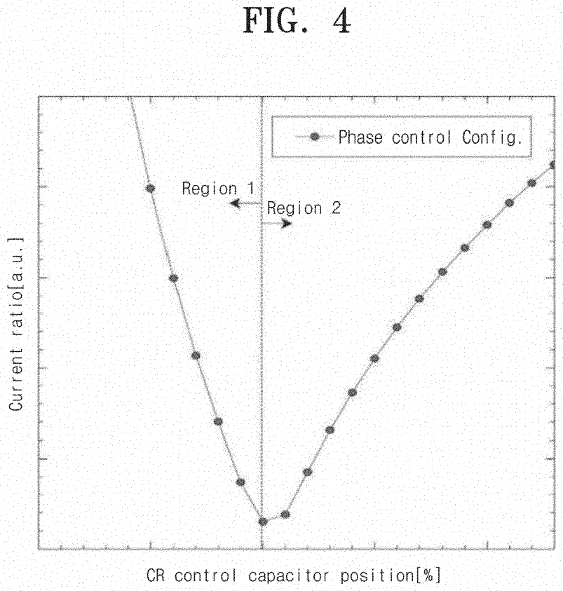

FIG. 4 is a diagram for describing adjusting a CR according to an exemplary embodiment of the present invention.

A graph of FIG. 4 shows a change in CR value by controlling the second capacitor 432. Referring to FIG. 4, it may be confirmed that the CR values are divided into two regions Region 1 and Region 2 based on the resonance by adjusting the second capacitor 432. According to the exemplary embodiment of FIG. 4, the regions may be divided into a region having a lower capacitance based on the resonance and a region having a higher capacitance based on the resonance. At this time, the region having the lower capacitance based on the resonance is defined as a first region and the region having the higher capacitance based on the resonance is defined as a second region.

According to the present invention, in the first region, a phase between an inner current and an outer current is fixed to a phase of 0° [symbol] . In the second region, it has been confirmed that a phase between an inner coil and an outer coil may be controlled in a range of 0° [symbol] to 180° [symbol] . This can be confirmed through a simulation results to be described below.

According to an exemplary embodiment of FIG. 4, the second capacitor 432 may be controlled to control the phase between the inner coil and the outer coil. At this time, the range of the first capacitor value may be in the range of 20 pF to 25 pF. According to another exemplary embodiment, in the case of an exemplary embodiment in which higher power is required, the range of the first capacitor value may have values of 180 pF to 185 pF, which is a range of higher values.

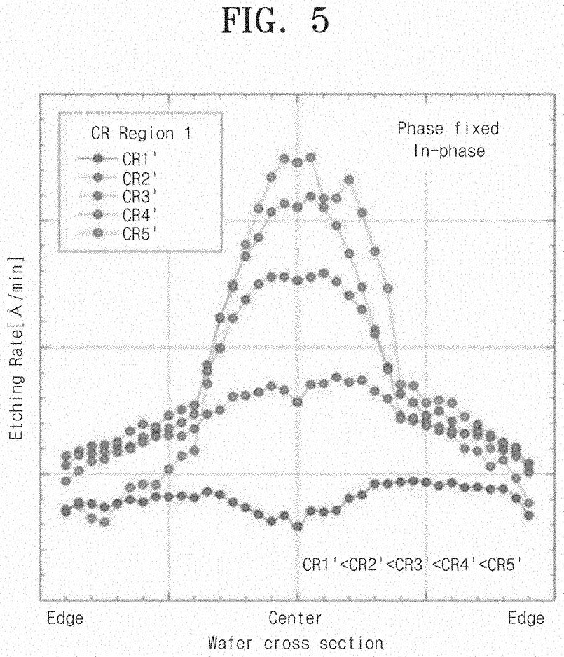

FIG. 5 is a diagram for describing performing a control in a first region according to an exemplary embodiment of the present invention.

FIG. 5 illustrates a radial etching rate profile of a wafer for different CRs in the first region. According to the first region, it is shown that the CR is controlled through various references in a range of CR1′ to CR2′, but it can be confirmed that there is a problem that only the etching rate is still adjusted in the center region and the etching rate in the edge region is not adjusted.

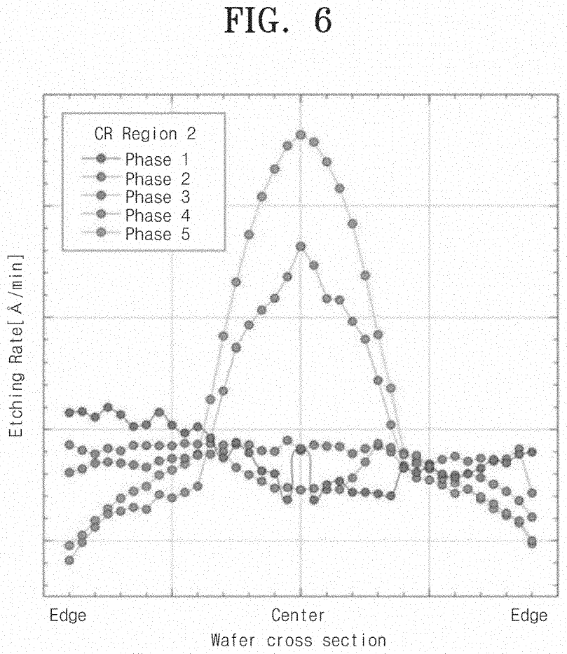

FIG. 6 is a diagram for describing performing a control in a second region according to an exemplary embodiment of the present invention.

FIG. 6 illustrates a radial etching rate profile of a wafer for different CRs in the second region. According to the second region, it is shown a case where the CR is not adjusted, but the phases are adjusted in the range of phase 1 to phase 5, respectively. In this case, it can be confirmed that the etching rate in the edge region as well as the etching rate in the center region may also be uniformly controlled.

That is, in the present invention, it can be confirmed that there is an effect of adjusting the etching rate in the edge region by performing the phase control in the second region. Such an effect will be described by controlling a phase difference between the inner and outer coil currents in the second region.

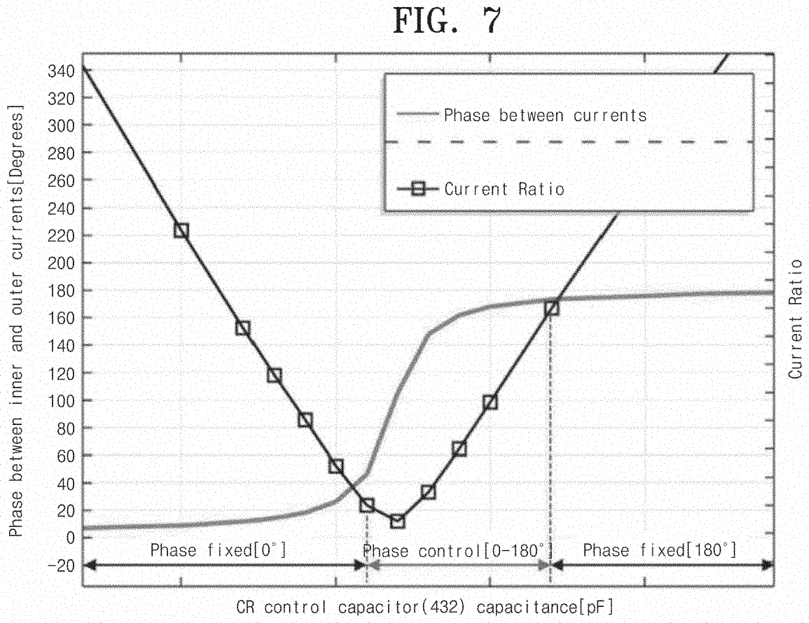

FIG. 7 is a diagram for describing performing a CR and a phase control by adjusting a capacitance of a second capacitor 432 according to an exemplary embodiment of the present invention.

Referring to FIG. 7, an X axis represents the capacitance of the second capacitor 432, a left Y axis represents a phase difference between the first antenna and the second antenna, and a right Y axis represents a CR.

According to the X axis of FIG. 7, it can be confirmed that respective periods may be divided into a phase fixed period and a phase control period through the capacitance adjustment of the second capacitor 432. According to an exemplary embodiment, the phase control period through the capacitance adjustment of the second capacitor 432 may be a region corresponding to the second region (Region 2) in FIG. 4. According to an exemplary embodiment, the phase control is impossible through the capacitance adjustment of the second capacitor 432, and the phase fixed region may be a region corresponding to the first region (Region 1) in FIG. 4.

Referring to FIG. 7, the CR may be adjusted by adjusting the capacitance of the second capacitor 432. At this time, the CR may have a tendency having a resonance at a predetermined point. The phase control at the predetermined point may be performed by adjusting the capacitance of the second capacitor 432. The predetermined point at this time may be a range having a larger capacitance than the resonance of the second capacitor 432. At this time, the phase to be controlled may be a phase difference between the first current flowing in the first antenna and the second current flowing in the second antenna. The phase controlled by the capacitance of capacitor 432 may be adjusted between 0° to 180°. According to FIG. 7, it can be confirmed that the phase control is possible in the second region by adjusting the capacitance of the second capacitor 432.

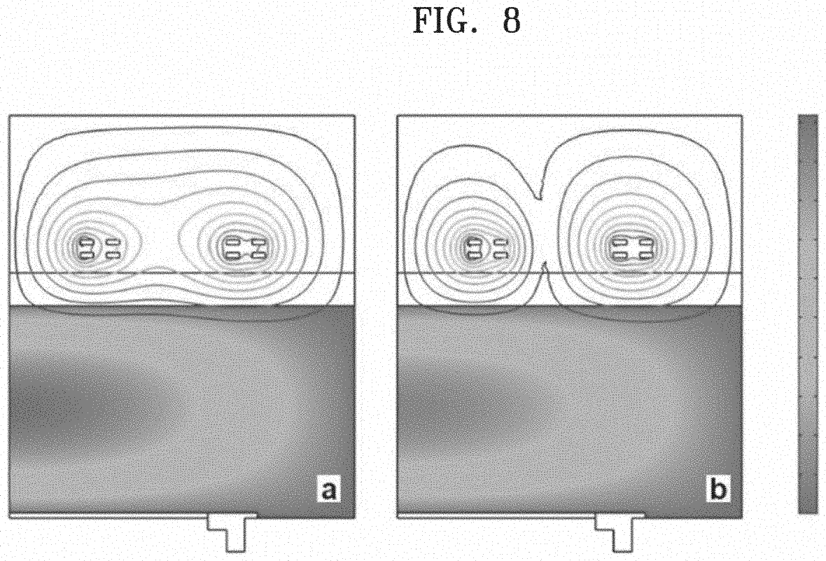

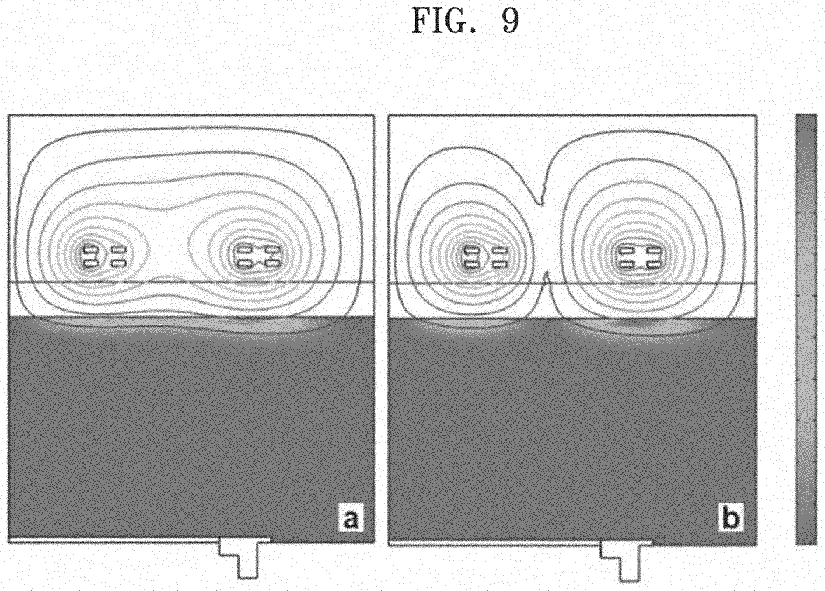

FIGS. 8 and 9 are diagrams illustrating a simulating result according to an exemplary embodiment of the present invention.

FIG. 8 is a diagram illustrating an electric field strength contour and electron density around an antenna coil in the case of CR=| (first region, θ=0° [symbol] ) and CR=1 (second region, θ=160° [symbol] ). According to FIG. 8, in the case of controlling the phase in the second region, it can be confirmed that the electron density in the center of the chamber is reduced and the contour of the electric field intensity is changed.

FIG. 9 is a diagram illustrating an electric field strength contour around an antenna coil and power deposition strength below a dielectric substance window in the case of CR=1 (first region, θ=0° [symbol] ) and CR=1 (second region, θ=160° [symbol] ). According to FIG. 9, it can be confirmed that the power deposition below an outer antenna coil is increased, and as a result, it can be confirmed that the controllability of the etching rate of the edge region is improved.

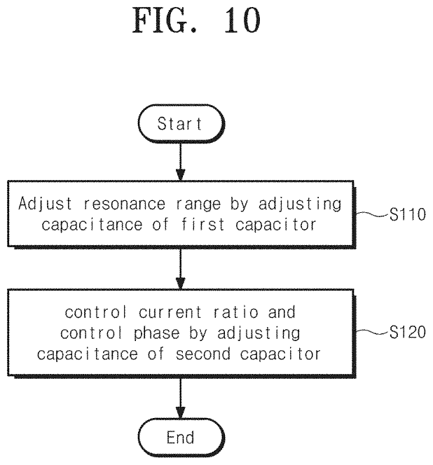

FIG. 10 is a diagram illustrating a control method of a plasma generating apparatus according to an exemplary embodiment of the present invention.

According to FIG. 10, in the present invention, the capacitance of the first capacitor may be adjusted to adjust a primary resonance range (S110). Then, the capacitance of the second capacitor may be adjusted to perform a current ratio control and a phase control to be applied to the first antenna and the second antenna (S120). At this time, the phase control may be controlled at 0 to 180° [symbol] . More specifically, the phase control may be controlled by adjusting the capacitance value of the second capacitor in a phase control range of the second capacitor. At this time, the phase control range of the second capacitor may be a region where the capacitance of the second capacitor is higher based on the resonance of the second antenna.

As such, the etching rate may be controlled from the outside of the substrate through control of the second capacitor.

That is, according to the present invention, there are disclosed a plasma generating apparatus including a current distributor capable of controlling the resonance and the phase and a substrate treating apparatus including the same. The current distributor according to the present invention includes two variable capacitors to control the phase between the inner coil and the outer coil of the antenna at the same time and control the CR similar to the existing circuit. This may be controlled by adjusting the second capacitor. Further, the capacitance of the first capacitor of the two variable capacitors is adjusted to improve the matching between tools of different chambers. The TTTM and resonance control may also be performed by adjusting the capacitance of the first capacitor. The etching rate in the edge region of the wafer may be adjusted by adjusting the capacitance of the second capacitor.

It is to be understood that the exemplary embodiments are presented to assist in understanding of the present invention, and the scope of the present invention is not limited, and various modified exemplary embodiments thereof are included in the scope of the present invention. The drawings provided in the present invention are only illustrative of an optimal exemplary embodiment of the present invention. The technical protection scope of the present invention should be determined by the technical idea of the appended claims, and it should be understood that the technical protective scope of the present invention is not limited to the literary disclosure itself in the appended claims, but the technical value is substantially affected on the equivalent scope of the invention.

1. A substrate treating apparatus of treating a substrate, comprising:
a chamber having a space for treating the substrate therein;
a support unit supporting the substrate in the chamber;
a gas supply unit supplying gas into the chamber; and
a plasma generation unit exciting the gas in the chamber into a plasma state,
wherein the plasma generation unit includes
a high frequency power supply;
a first antenna;
a second antenna; and
a matcher connected between the high frequency power supply and the first and second antennas,
wherein the matcher includes a current distributor distributing a current to the first antenna and the second antenna,
the current distributor includes
a first capacitor disposed between the first antenna and the second antenna;
a second capacitor connected with the second antenna in series; and
a third capacitor connected with the second antenna in parallel,
wherein the first capacitor and the second capacitor are provided as variable capacitors.

2. The substrate treating apparatus of claim 1, wherein the third capacitor is provided as a fixed capacitor, and
the current distributor is disposed between the high frequency power supply, the first antenna and the second antenna.

3. The substrate treating apparatus of claim 2, wherein the current distributor distributes the current to the first antenna and the second antenna by adjusting the capacitances of the first capacitor and the second capacitor.

4. The substrate treating apparatus of claim 1, wherein the current distributor controls a current ratio of the currents flowing in the first antenna and the second antenna by adjusting the capacitance of the second capacitor.

5. The substrate treating apparatus of claim 4, wherein the current distributor performs a phase control between the currents flowing in the first antenna and the second antenna by adjusting the capacitance of the second capacitor.

6. The substrate treating apparatus of claim 5, wherein the current distributor sets a resonance range by adjusting the capacitance of the first capacitor within a predetermined range.

7. The substrate treating apparatus of claim 6, wherein the capacitance range of the first capacitor is 20 to 25 pF or 180 to 185 pF.

8. A plasma generating apparatus of generating plasma in a chamber in which a process of treating a substrate is performed, comprising:
a high frequency power supply;
a first antenna;
a second antenna; and
a matcher connected between the high frequency power supply and the first and second antennas,
wherein the matcher includes a current distributor distributing a current to the first antenna and the second antenna,
the current distributor includes
a first capacitor disposed between the first antenna and the second antenna;
a second capacitor connected with the second antenna in series; and
a third capacitor connected with the second antenna in parallel,
wherein the first capacitor and the second capacitor are provided as variable capacitors.

9. The plasma generating apparatus of claim 8, wherein the third capacitor is provided as a fixed capacitor, and
the current distributor is disposed between the high frequency power supply, the first antenna and the second antenna.

10. The plasma generating apparatus of claim 9, wherein the current distributor distributes the current to the first antenna and the second antenna by adjusting the capacitances of the first capacitor and the second capacitor.

11. The plasma generating apparatus of claim 8, wherein the current distributor controls a current ratio of the currents flowing in the first antenna and the second antenna by adjusting the capacitance of the second capacitor.

12. The plasma generating apparatus of claim 11, wherein the current distributor performs a phase control between the currents flowing in the first antenna and the second antenna by adjusting the capacitance of the second capacitor.

13. The plasma generating apparatus of claim 12, wherein the current distributor sets a resonance range by adjusting the capacitance of the first capacitor within a predetermined range.

14. The plasma generating apparatus of claim 13, wherein the capacitance range of the first capacitor is 20 to 25 pF or 180 to 185 pF.

15.-20. (canceled)
